(19) United States
(12) Patent Application Publication
(10) Pub. No.: US 2008/0185660 A1
(43) Pub. Date: Aug. 7, 2008

(54) Semiconductor device and method of forming the same

(75) Inventor: Jung-Hun Choi, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/012,252

(22) Filed: Feb. 1, 2008

(30) Foreign Application Priority Data
Feb. 2, 2007 (KR) 10-2007-0011086

(51) Int. Cl. H01L 27/092; H01L 21/8238

(52) U.S. Cl. 257/371; 438/218; 257/E27.067; 257/E21.644

(57) ABSTRACT

The invention provides a semiconductor device and a method of forming the same. The method of forming the semiconductor device includes preparing a P-type semiconductor substrate including a low-voltage NMOS region, low-voltage PMOS region, high-voltage NMOS region, and high-voltage PMOS region; forming an N-well in the low-voltage PMOS region and high-voltage PMOS region; forming a P-well in the low-voltage NMOS region and high-voltage NMOS region; and forming a bouncing protection layer in a lower portion of the P-well of the low-voltage PMOS region.

### CROSS REFERENCE TO RELATED APPLICATION

This U. S non-provisional patent application claims priority under 35 U.S.C. §119 to Korean Patent Application No. 10-2007-0011086 filed on Feb. 2, 2007, the entirety of which is hereby incorporated by reference.

### FIELD OF INVENTION

The present invention relates to a semiconductor device and method of forming the same, more particularly, the present invention relates to a semiconductor device having a high-voltage region and a low-voltage region and method of forming the same.

### BACKGROUND OF INVENTION

The semiconductor device can include a high-voltage region and a low-voltage region. The NMOS region of a high-voltage region and the NMOS region of a low-voltage region can both include a P-well. The P-well of the high-voltage NMOS region and the P-well of the low-voltage NMOS region can be electrically connected by a semiconductor substrate. If the semiconductor substrate is a P-type semiconductor substrate, a bouncing effect can occur, which, for example, the high voltage supplied to the high-voltage NMOS region can affect the low-voltage NMOS region.

Four steps of a photo-lithography process can be performed to form wells in a high-voltage NMOS region, high-voltage PMOS region, low-voltage NMOS region, and low-voltage PMOS region, respectively. However, this four-step photo-lithography process can increase processing cost.

### SUMMARY

In accordance with one aspect of the present invention, provided is a semiconductor device including: a semiconductor substrate of a first conduction type, the semiconductor substrate including a low-voltage region and a high-voltage region; a first well and a second well of the first conduction type, the first well and the second well provided in the low-voltage region and high-voltage region, respectively; and a bouncing protection layer of a second conduction type, wherein the second conduction type is an opposite conduction type from the first conduction type, the bouncing protection layer provided in a lower portion of the first well of the low-voltage region.

The first conduction type can be a P-type, and the second conduction type can be an N-type.

The low-voltage region can include a low-voltage NMOS region and a low-voltage PMOS region, the high-voltage region can include a high-voltage NMOS region and a high-voltage PMOS region, the first well can be provided in the low-voltage NMOS region, and the second well can be provided in the high-voltage NMOS region.

The semiconductor device can further comprise: a third well of the second conduction type provided in the low-voltage PMOS region; and a fourth well of the second conduction type provided in the high-voltage PMOS region.

The bouncing protection layer can be further provided in a lower portion within the third well.

The semiconductor device can further comprise device isolation layers isolating the high-voltage NMOS region, high-voltage PMOS region, low-voltage NMOS region, and low-voltage PMOS region, respectively.

The bouncing protection layer can be provided at a level lower than a bottom surface of the device isolation layers.

In accordance with another aspect of the present invention, provided is a method of forming a semiconductor device that includes preparing a P-type semiconductor substrate including a low-voltage NMOS region, low-voltage PMOS region, high-voltage NMOS region, and high-voltage PMOS region; forming an N-well in the low-voltage PMOS region and high-voltage PMOS region; forming a P-well in the low-voltage NMOS region and high-voltage NMOS region; and forming a bouncing protection layer in a lower portion of the P-well of the low-voltage PMOS region.

Forming the P-well and the N-well can include: implanting N-type impurities on the surface of the semiconductor substrate to form a preliminary N-well; and implanting P-type impurities in the low-voltage NMOS region and the high-voltage NMOS region.

The method can further comprise forming device isolation layers isolating the low-voltage NMOS region, low-voltage PMOS region, high-voltage NMOS region, and high-voltage PMOS region, respectively.

Forming the bouncing protection layer can include: forming a high-voltage gate insulation layer on the semiconductor substrate; forming a photoresist pattern covering the high-voltage NMOS region and the high-voltage PMOS region; and performing an ion-implanting process of N-type impurities, using the photoresist pattern as a mask.

The method can include forming the bouncing protection layer at a level lower than a bottom surface of the device isolation layer.

The method can include further forming the bouncing protection layer in a lower portion of the N-well of the low-voltage PMOS region.

The method can include, after forming the bouncing protection layer: performing an etch process to remove the high-voltage gate insulation layer covering the low-voltage NMOS region and the low-voltage PMOS region, the etch process performed using the photoresist pattern; forming a low-voltage gate insulation layer covering the low-voltage NMOS region and the low-voltage PMOS region; and forming gate patterns in the low-voltage NMOS region, low-voltage PMOS region, high-voltage NMOS region, and the high-voltage PMOS region, respectively.

### BRIEF DESCRIPTION OF THE DRAWINGS

FIG. 1 is a plan view of an example embodiment of a semiconductor device according to an aspect of the present invention.

FIG. 2 is a cross-sectional view of an example embodiment of a semiconductor according an aspect of the present invention.

FIGS. 3A to 3E are cross-sectional views illustrating an example embodiment of a method of forming a semiconductor device according to an aspect of the present invention.

### DETAILED DESCRIPTION OF PREFERRED EMBODIMENTS

Embodiments in accordance with aspects of the present invention will now be described more fully hereinafter with reference to the accompanying drawings, in which preferred embodiments of the invention are shown. This invention, however, can be embodied in many different forms and should not be construed as limited to the embodiments set forth herein.

In the drawings, the thicknesses of layers and regions are exaggerated for clarity. It will also be understood that when a layer is referred to as being “on” another layer or substrate, it can be directly on the other layer or substrate, or intervening layers can also be present. It will be understood that when an element is referred to as being “connected” or “coupled” to another element, it can be directly connected or coupled to the other element or intervening elements can be present. In contrast, when an element is referred to as being “directly on” or “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.). Like numbers refer to like elements throughout.

It will be understood that, although the terms first, second, etc. are be used herein to describe various elements, these elements should not be limited by these terms. These terms are used to distinguish one element from another, but not to imply a required sequence of elements. For example, a first element can be termed a second element, and, similarly, a second element can be termed a first element, without departing from the scope of the present invention. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms ¢comprises,” “comprising,” “includes” and/or “including,” when used herein, specify the presence of stated features, steps, operations, elements, and/or components, but do not preclude the presence or addition of one or more other features, steps, operations, elements, components, and/or groups thereof.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (e.g., rotated 90 degrees or at other orientations) and the spatially relative descriptors used herein interpreted accordingly.

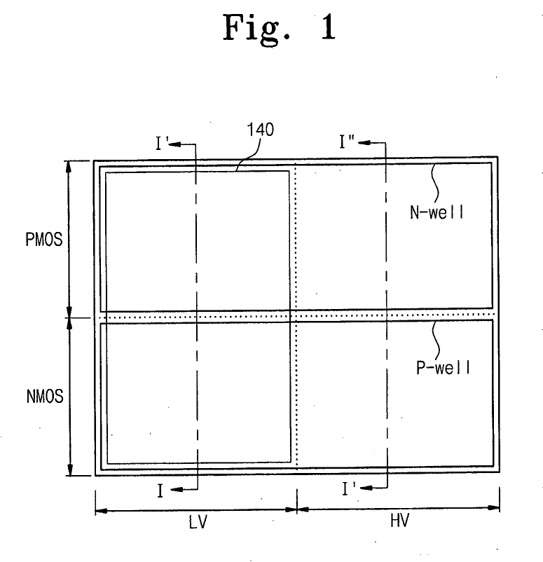

FIG. 1 is a plan view of an example embodiment of a semiconductor device according to an aspect of the present invention.

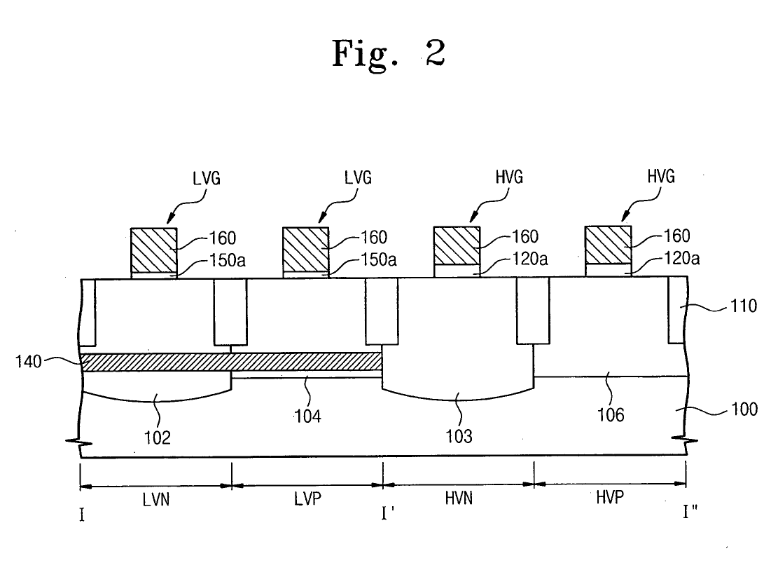

Referring to FIG. 1, a low-voltage region LV and a high-voltage region HV are illustrated, and an NMOS region and a PMOS region are illustrated. A P-well is provided in the NMOS region, and an N-well is provided in the PMOS region. A bouncing protection layer 140, which will be described with reference to FIG. 2, can be formed in the low-voltage region LV. Accordingly, the bouncing protection layer 140 can prevent the high voltage supplied to high-voltage region HV from affecting the low-voltage region LV.

FIG. 2 is a cross-sectional view of an example embodiment of a semiconductor device according to an aspect of the present invention. FIG. 2 is a combination of a cross-sectional view cut along the line I-I′ of FIG. 1 and a cross-sectional view cut along the line I′- I″, put together for illustrative purposes.

Referring to FIG. 2, a semiconductor substrate 100 is provided, the semiconductor substrate 100 including a low-voltage NMOS region LVN, a low-voltage PMOS region LVP, a high-voltage NMOS region HVN, and a high-voltage PMOS region HVP. A first well 102 and a second well 103, both of a first conduction type is provided in the low-voltage NMOS region LVN and high-voltage NMOS region HVN, respectively. A third well 104 and a fourth well 106, both of a second conduction type are provided on the low-voltage PMOS region and high-voltage PMOS region HVP, respectively. The second conduction type is opposite to the first conduction type. The semiconductor substrate 100 can be a first conduction type. The first conduction type can be a P-type, and the second conduction type can be an N-type.

A bouncing protection layer 140 is provided in the lower portion within the first well 102. The bouncing protection layer 140 is of a second conduction type. The bouncing protection layer 140 can be further provided in the lower portion within the third well 104. The bouncing protection layer 140 can prevent the high voltage supplied to the high-voltage NMOS region HVN from affecting the low-voltage NMOS region LVN. The high-voltage NMOS region HVN and the low-voltage NMOS region LVN can be electrically insulated by the bouncing protection layer 140.

Device isolation layers 110 are provided, which isolate the low-voltage NMOS region LVN, low-voltage PMOS region LVP, high-voltage NMOS region HVN, and high-voltage PMOS region HVP, respectively. The bouncing protection layer 140 can be provided at a level lower than the bottom surface of the device isolation layers 110.

A low-voltage gate pattern LVG is provided in the low-voltage NMOS region LVN and low-voltage PMOS region LVP. The low-voltage gate pattern LVG can include a low-voltage gate insulation pattern 150a and a gate electrode 160. A high-voltage gate pattern HVG is provided in the high-voltage NMOS region HVN and high-voltage PMOS region HVP. The high-voltage gate pattern HVG can include a high-voltage gate insulation pattern 120a and a gate electrode 160. The thickness of the high-voltage gate insulation pattern 120a can be larger than that of the low-voltage gate insulation pattern 150a.

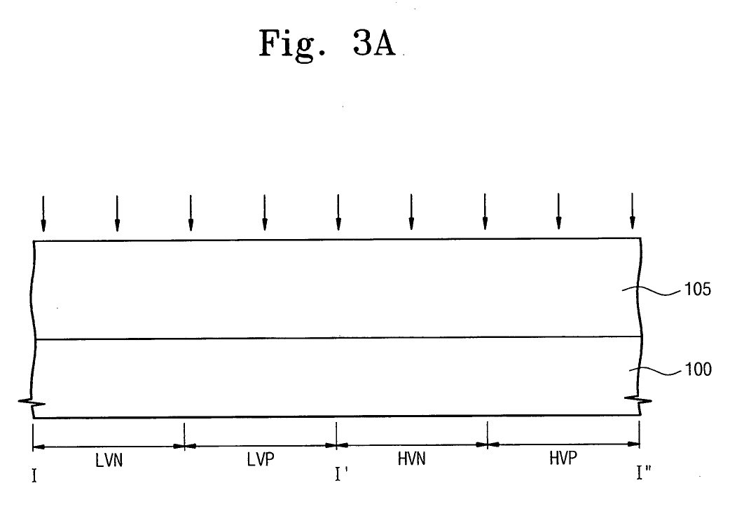

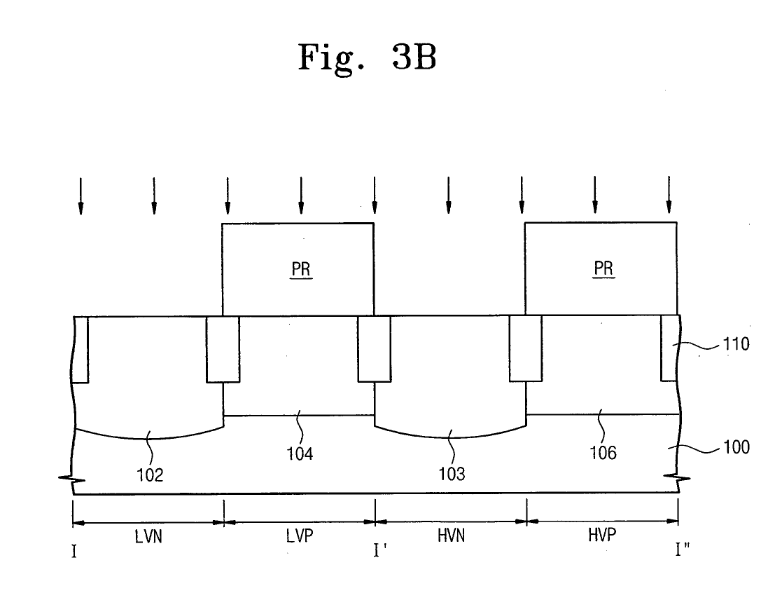

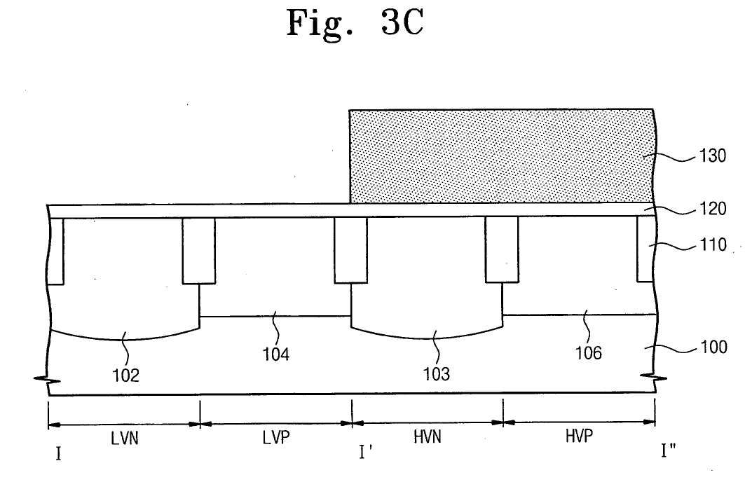

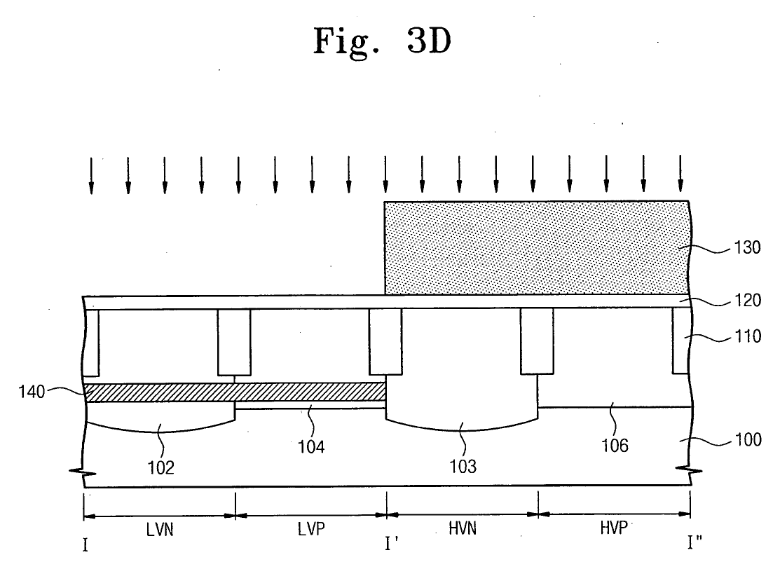

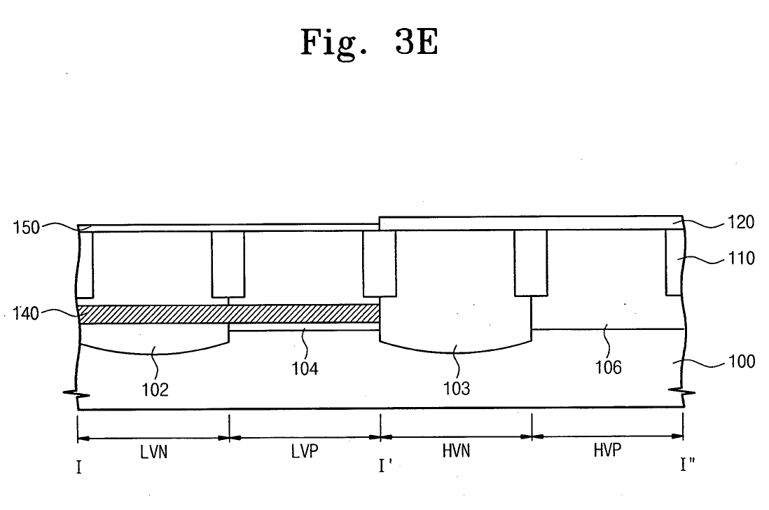

FIGS. 3A to 3E are cross-sectional views illustrating an example embodiment of a method of forming a semiconductor substrate according to an aspect of the present invention.

Referring to FIG. 3a, a P-type semiconductor substrate 100 is provided, the P-type semiconductor substrate 100 including a low-voltage NMOS region LVN, a low-voltage PMOS region LVP, a high-voltage NMOS region HVN, and a high-voltage PMOS region HVP. N-type impurities are implanted in the semiconductor substrate 100 to form an preliminary N-well 105.

Referring to FIG. 3B, P-type impurities are implanted in the low-voltage NMOS region LVN and high-voltage NMOS region HVN to form a first P-well 102 and a second P-well 103, respectively. As the first P-well 102 and the second P-well 103 are formed, a first N-well 104 and a second N-well 106 are formed in the low-voltage PMOS region LVP and high-voltage PMOS region HVP, respectively. The first P-well 102 and the second P-well 103 can be formed by implanting P-type impurities having a higher impurity density than that of the preliminary N-well. The first P-well 102, the second P-well 103, the first N-well 104, and the second N-well 106 can be formed using a one-step photo-lithography process.

Device isolation layers 110 are provided, the device isolation layers 110 isolating the low-voltage NMOS region LVN, the low-voltage PMOS region LVP, the high-voltage NMOS region HVN, and the high-voltage PMOS region HVP. A method of forming the device isolation layers 110 can include etching the semiconductor substrate 100 to form a trench, and forming an insulation layer that fills the trench.

Referring to FIG. 3C, a high-voltage gate insulation layer 120 is formed on the semiconductor substrate 100. The high-voltage gate insulation layer 120 can be formed using a thermal oxidation process. The high-voltage gate insulation layer 120 can be provided to have a thickness suitable for the characteristics of high voltage (for example, 17V to 20V), as will be appreciated by those skilled in the art. A photoresist pattern 130 can be provided, the photoresist pattern 130 covering the high-voltage NMOS region HVN and the high-voltage PMOS region HVP.

Referring to FIG. 3D, an ion implantation process is performed to form a bouncing protection layer 140 in the low-voltage NMOS region LVN and low-voltage PMOS region LVP, using the photoresist pattern 130 as a mask. The bouncing protection layer 140 can be formed in the lower portion within the first P-well 102. The bouncing protection layer 140 can be further formed in the lower portion within the first N-well 104. The bouncing protection layer 140 can be formed at a level lower than the bottom surface of the device isolation layer 110. The bouncing protection layer is an N-type, in this embodiment. In the ion implantation process, the high-voltage gate insulation layer 120 can be used as a screen oxide that prevents damage in the semiconductor substrate 100.

The bouncing protection layer 140 can serve as a mechanism to prevent the high voltage supplied to the high-voltage NMOS region HVN from affecting the low-voltage NMOS region LVN. The high-voltage NMOS region HVN and the low-voltage NMOS region LVN can be electrically insulated by the bouncing protection layer 140.

Referring to FIG. 3E, the high-voltage gate insulation layer 120 is removed, the high-voltage gate insulation layer 120 covers the high-voltage NMOS region HVN and the low-voltage NMOS region LVN. Removing the high-voltage gate insulation layer 120 can include a wet etching process. The photoresist pattern 130 can be used as an etch mask of the wet etching process, and also can be used as a mask for an ion implantation process to form the bouncing protection layer 140. Accordingly, an additional photo-lithography process is not necessary to form the bouncing protection layer 140.

A low-voltage gate insulation layer 150 is formed on the low-voltage NMOS region LVN and the low-voltage PMOS region LVP. The low-voltage gate insulation layer 150 can be formed using a thermal oxidation process. The low-voltage gate insulation layer 150 can be provided in a thickness suitable for the characteristics of a low voltage (for example, 1.8V to 3.3V), as will be appreciated by those skilled in the art. The low-voltage gate insulation layer 150 can be formed to have a smaller thickness than the high-voltage gate insulation layer 120.

According to an example embodiment, the photo-lithography process to form the P-well and N-well is decreased, a bouncing protection layer can be formed, the bouncing protection layer which electrically insulates the low-voltage NMOS region and the high-voltage NMOS region. Accordingly, a semiconductor device that electrically insulates a high voltage region and a low voltage region can be formed.

Although embodiments in accordance with aspects of the present invention have been described in connection with the accompanying drawings, the present invention is not limited thereto. It will be apparent to those skilled in the art that various substitutions, modifications, and changes can be thereto without departing from the scope and spirit of the invention. It is intended by the following claims to claim that which is literally described and all equivalents thereto, including all modifications and variations that fall within the scope of each claim.

What is claimed is:

1. A semiconductor device comprising:
a semiconductor substrate of a first conduction type, the semiconductor substrate including a low-voltage region and a high-voltage region;
a first well and a second well of the first conduction type, the first well and the second well provided in the low-voltage region and high-voltage region, respectively; and
a bouncing protection layer of a second conduction type, wherein the second conduction type is an opposite conduction type from the first conduction type, the bouncing protection layer provided in a lower portion of the first well of the low-voltage region.

2. The semiconductor device as in claim 1, wherein the first conduction type is a P-type, and the second conduction type is an N-type.

3. The semiconductor device as in claim 2, wherein the low-voltage region includes a low-voltage NMOS region and a low-voltage PMOS region, the high-voltage region includes a high-voltage NMOS region and a high-voltage PMOS region, the first well is provided in the low-voltage NMOS region, and the second well is provided in the high-voltage NMOS region.

4. The semiconductor device as in claim 3 further comprising:
a third well of the second conduction type provided in the low-voltage PMOS region; and
a fourth well of the second conduction type provided in the high-voltage PMOS region.

5. The semiconductor device as in claim 4, wherein the bouncing protection layer is further provided in a lower portion within the third well.

6. The semiconductor device as in claim 3 further comprising device isolation layers isolating the high-voltage NMOS region, high-voltage PMOS region, low-voltage NMOS region, and low-voltage PMOS region, respectively.

7. The semiconductor device as in claim 6, wherein the bouncing protection layer is provided at a level lower than a bottom surface of the device isolation layers.

8. A method of forming a semiconductor device comprising:
preparing a P-type semiconductor substrate including a low-voltage NMOS region, low-voltage PMOS region, high-voltage NMOS region, and high-voltage PMOS region;
forming an N-well in the low-voltage PMOS region and high-voltage PMOS region;
forming a P-well in the low-voltage NMOS region and high-voltage NMOS region; and forming a bouncing protection layer in a lower portion of the P-well of the low-voltage PMOS region.

9. The method as in claim 8, wherein forming the P-well and the N-well comprises:
implanting N-type impurities on the surface of the semiconductor substrate to form a preliminary N-well; and
implanting P-type impurities in the low-voltage NMOS region and the high-voltage NMOS region.

10. The method as in claim 8 further comprising:
forming device isolation layers isolating the low-voltage NMOS region, low-voltage PMOS region, high-voltage NMOS region, and high-voltage PMOS region, respectively.

11. The method as in claim 10, wherein the bouncing protection layer comprises:
forming a high-voltage gate insulation layer on the semiconductor substrate;
forming a photoresist pattern covering the high-voltage NMOS region and the high-voltage PMOS region; and
performing an ion-implanting process of N-type impurities, using the photoresist pattern as a mask.

12. The method as in claim 11, including forming the bouncing protection layer at a level lower than a bottom surface of the device isolation layer.

13. The method as in claim 11, including further forming the bouncing protection layer in a lower portion of the N-well of the low-voltage PMOS region.

14. The method as in claim 11, after forming the bouncing protection layer, further comprising:
performing an etch process to remove the high-voltage gate insulation layer covering the low-voltage NMOS region and the low-voltage PMOS region, the etch process performed using the photoresist pattern;
forming a low-voltage gate insulation layer covering the low-voltage NMOS region and the low-voltage PMOS region; and
forming gate patterns in the low-voltage NMOS region, low-voltage PMOS region, high-voltage NMOS region, and the high-voltage PMOS region, respectively.
